(19) United States
(12) Patent Application Publication
(10) Pub. No.: US 2025/0273623 A1
(43) Pub. Date: Aug. 28, 2025

(54) METHOD OF MANUFACTURING SEMICONDUCTOR DEVICES AND CORRESPONDING DEVICE

(71) Applicant: STMicroelectronics International N.V., Geneva (CH)

(72) Inventors: Olivier FRANIATTE, Grenoble (FR); Guendalina CATALANO, Milano (IT); Riccardo VILLA, Milano (IT); Didier SIGNORET, Polienas (FR)

(73) Assignee: STMicroelectronics International N.V., Geneva (CH)

(21) Appl. No.: 19/063,900

(22) Filed: Feb. 26, 2025

(30) Foreign Application Priority Data
Feb. 28, 2024 (IT) 102024000004300

(51) Int. Cl. H01L 23/00; H01L 21/56; H01L 23/31

(52) U.S. Cl. CPC H01L 24/82; H01L 21/56; H01L 23/3107; H01L 24/25; H01L 2224/25174; H01L 2224/2543; H01L 2224/82103

(57) ABSTRACT

A semiconductor chip is arranged on a die pad in a substrate including first and second sets of electrically conductive leads. Electrically conductive formations couple the semiconductor chip to electrically conductive leads in the first set using through mold vias that extend towards the semiconductor chip and towards electrically conductive leads in the first set. The through mold vias are laser direct structured through a layer of laser direct structuring (LDS) encapsulation material just like a pattern of stages of through mold vias that extend towards the semiconductor chip and towards electrically conductive leads in the further set of electrically conductive leads. Further stages of through mold vias are laser direct structured through a further layer of LDS encapsulation material molded onto the layer of LDS encapsulation material having the vias and the stages of through mold vias laser direct structured therethrough.

### PRIORITY CLAIM

This application claims the priority benefit of Italian Application for Patent No. 102024000004300, filed on Feb. 28, 2024, the content of which is hereby incorporated by reference in its entirety to the maximum extent allowable by law.

### TECHNICAL FIELD

The description relates to manufacturing semiconductor devices.

Solutions as described herein can be applied to integrated circuit (IC) semiconductor devices including multi-level metallization.

Quad Flat No-lead (QFN) packages, such as QFN multi-row (signal QFN packages, for instance) or leadframe (L/F) packages using so-called “flying” pads are exemplary of IC semiconductor devices where solutions as described herein can be applied.

### BACKGROUND

Metallization provided using the technology currently referred to as laser direct structuring (LDS), also known under other designations such as laser direct writing (LDW), direct copper interconnect (DCI) or the trade designation LISIPACK™, rely on continuity of laser-patterned traces and vias (grounded during electroplating).

In that context, providing multi-level structure involves forming isolated vias and traces to provide stacked vias. This may involve forming deep vias extending through several LDS molding compound levels.

Due to aspect ratio constraints related to the plating process, these deep vias tend to be large vias, which puts constraints on interconnection density and package miniaturization.

Solutions have been proposed wherein temporary ground connections are used in providing die-to-die connections, for instance. These solutions may however turn out to be fairly complex in terms of equipment (they may involve modification of the plating bath, for instance) and/or processes involved (a photo-resist patterning step, may be required, for instance).

There is a need in the art to contribute in addressing the issues above.

### SUMMARY

One or more embodiments relate to a method.

One or more embodiments relate to a corresponding integrated circuit (IC) semiconductor device.

Solutions as described herein may involve forming, in a level of laser direct structuring (LDS) molding material, a continuous pattern of vias and traces, and, after metallization, some portions of the metallization pattern can be possibly isolated by laser ablation of sacrificial traces. Isolated vias can thus be formed and stacked.

Solutions as described herein facilitate avoiding aspect ratio/size issues, maintaining a dense circuit layout, thus providing high-density high-performance multi-row Quad Flat No-lead (QFN) packages (with large conductive traces, for instance).

Solutions as described herein may involve forming an isolated via in an LDS molding compound layer and activating (structuring) in the LDS layer a continuous pattern of vias and traces that comprises at least one sacrificial trace connecting the isolated via to the continuous pattern, followed by plating this continuous pattern through electroplating and then laser ablating sacrificial traces to electrically isolate the via from the continuous pattern.

### BRIEF DESCRIPTION OF THE DRAWINGS

One or more embodiments will now be described, by way of example only, with reference to the annexed figures, wherein:

FIG. 1A is generally illustrative of an integrated circuit (IC) semiconductor device;

FIG. 1B illustrates certain critical issues that may arise in producing a multi-level (integrated circuit) semiconductor device;

FIG. 1C illustrates how these issues can be dealt with to solutions as described herein; and

FIGS. 2A through 2R illustrate possible steps in a sequence according to solutions as described herein.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

The meaning of various terms or designations that may be used or may be referred to in this description will now be briefly recalled. This is primarily by way of immediate reference, being otherwise understood that these terms or designations are well known to those of skill in the art of manufacturing integrated circuit (IC) semiconductor devices.

Package is a case that surrounds the circuit material to protect it from corrosion or physical damage and allow mounting of the electrical contacts connecting it to a printed circuit board.

Laser direct structuring (LDS) is a combination of laser patterning and plating processes to create electrical interconnections obtained via laser “writing” (hence the possible designation of laser direct writing (LDW)). LDS facilitates device interconnection with a substrate via metal—for instance copper: hence the possible designation direct copper interconnect (DCI)—directly grown with additive processes. Laser direct structuring (LDS, LDW, DCI) is a technology based on the structuring (writing) of a plastic material by a laser source. The lasered traces are then plated in order to provide a conductive patterning.

Laser Induced Strip Interconnection (LISI) is another designation sometimes applied to that technology. In the LISIPACK™ family of ST products, an LDS molding compound is used to cover (encapsulate) a die and electrically conductive lines (vias, traces) are “structured” in the LDS molding compound.

As discussed in the introductory portion of this description, LDS is a technology based on the structuring of a plastic material by a laser source.

LDS is now used in various sectors of the industrial and consumer electronics markets, for instance for high-performance antenna integration, where an antenna design can be directly formed onto a molded plastic part.

In an exemplary process, the molded parts can be produced with commercially available insulating resins that include additives suitable for the LDS process; a broad range of resins such as polymer resins like PC, PC/ABS, ABS, LCP and LDS additives such as copper-based, copper-chromite seed-forming additives are currently available for that purpose.

A laser beam can be used to transfer (“structure”, “activate”, “write”) a desired electrically conductive pattern onto an LDS molding compound that may then be subjected to metallization to finalize a desired conductive pattern.

Metallization may involve electroless plating followed by electrolytic plating (electroplating).

Electroless plating, also known as chemical plating, is a class of industrial chemical processes that creates metal coatings on various materials by autocatalytic chemical reduction of metal cations in a liquid bath.

In electrolytic plating, an electric field between an anode and a workpiece, acting as a cathode, forces positively charged metal ions to move to the cathode where they give up their charge and deposit themselves as metal on the surface of the workpiece.

LDS can be applied to IC package families where conventional wire bonding is replaced with copper plated vias and lines (traces).

Reference is made to United States Patent Application Publication Nos. 2018/0342453 A1, 2019/0115287 A1, 2020/0203264 A1, 2020/0321274 A1, 2021/0050226 A1, 2021/0050299 A1, 2021/0183748 A1, 2021/00305191 A1, 2021/0305203 A1 or 2023/0035470 A1 (all assigned to companies of the STMicroelectronics group and incorporate herein by reference) are exemplary of the possibility of applying LDS technology in manufacturing semiconductor devices.

For instance, LDS technology facilitates replacing wires, clips or ribbons with lines/vias created by laser beam processing of an LDS material followed by metallization (growing metal such as copper via a plating process, for instance).

Electrically conductive coupling can be provided in the LDS material (once consolidated, via thermosetting, for instance): as through mold vias (TMVs) that extend through an LDS encapsulation between a top (front) surface of the LDS encapsulation and electrically-conductive pads at the front or top surface of a chip or die and/or corresponding leads in a leadframe, and as electrically-conductive lines or traces that extend at the front or top surface of the LDS encapsulation and electrically couple through mold vias to provide a desired electrical connection (routing) pattern.

Electrical components (passive components such as resistors, for instance) may be possibly arranged along one or more of the lines or traces.

Providing such electrically conductive formations using LDS material thus essentially involves: structuring (writing, activating) these formations in the LDS material at the desired locations (by laser drilling, for instance), and growing electrically conductive material (a metal such as copper, for instance) at the locations previously structured (activated).

As discussed in the introductory portion to this description, extending recourse to LDS technology to multi-level metallization may involve forming isolated vias and traces to provide stacked vias.

Arrangements related to such an approach are disclosed in the literature as witnessed, for instance, in various non-patent documents.

By way of example, stacked vias in the back end of line (BEOL), namely that portion of the IC fabrication process where the transistors, capacitors, resistors, and so on are interconnected via wiring on the wafer, are discusses at the URL https://www.semiconductor-digest.com/scaling-the-beol-a-toolbox-filled-with-new-processes-boosters-and-conductors/.

Stacked vias in a redistribution layer, RDL are discussed at the URL https://www.researchgate.net/publication/284356004_Redistribution_layers_RDLs_for_25D3D_IC_integration.

Stacked vias in a printed circuit board, PCB are discussed at the URL https://www.semanticscholar.org/paper/Reliability-testing-for-microvias-in-printed-wire-Birch/9f90632c0dc0ba11826ec29a351f77655969ac6b.

Essentially, these documents disclose stacked vias patterned through photolithographic techniques (photo-resist masks used for patterning). This may involve forming deep vias.

Due to aspect ratio constraints during plating, such deep vias extending through several LDS molding compound levels tend to be large vias, which puts constraints on interconnection density and package miniaturization.

Solutions have been proposed wherein temporary ground connections are used to facilitate providing die-to-die connections, for instance.

For instance, United States Patent Application Publication No. 2023/0035445 A1 (assigned to companies of the STMicroelectronics group and incorporated herein by reference) discloses molding an encapsulation of laser direct structuring (LDS) material onto first and second semiconductor dice. A die-to-die coupling formation between the first and second semiconductor dice includes die vias extending through the LDS material to reach the first and second semiconductor dice and a die-to-die line extending at a surface of the encapsulation between the die vias. After laser activating and structuring selected locations of the surface of the encapsulation for the die vias and die-to-die line, the locations are placed into contact with an electrode that provides an electrically conductive path. Metal material is electrolytically grown onto the locations of the encapsulation by exposure to an electrolyte carrying metal cations. The metal cations are reduced to metal material via a current flowing through the electrically conductive path provided via the electrode. The electrode is then disengaged from contact with the locations having metal material electrolytically grown thereon.

United States Patent Application Publication No. 2022/0199426 A1 (likewise assigned to companies of the STMicroelectronics group and incorporated herein by reference) discloses a method of manufacturing a multi-die semiconductor device, wherein a metal leadframe includes a die pad and electrically-conductive leads arranged around the die pad. First and second semiconductor dice are arranged on the die pad. A laser-activatable material is disposed on the dice and leads, and a set of laser-activated lines is patterned, including a first subset coupling selected bonding pads of the dice to selected leads, a second subset coupling selected bonding pads amongst themselves, and a third subset coupling the lines in the second subset to at least one line in the first subset. A first metallic layer is deposited onto the laser-activated lines to provide first, second and third subsets of electrically-conductive lines. A second metallic layer is selectively deposited onto the first and second subsets by electroplating to provide first and second subsets of electrically-conductive tracks. The electrically-conductive lines in the third subset are selectively removed.

It is noted that in the arrangement of United States Patent Application Publication No. 2022/199426 A1 (already noted above) the third subset—that is, the sacrificial connections—is not electroplated and only receives electroless deposition.

These solutions may turn out to be fairly complex in terms of equipment (they may involve modification of the plating bath, for instance) and/or processes involved (a photo-resist patterning step, may be required, for instance).

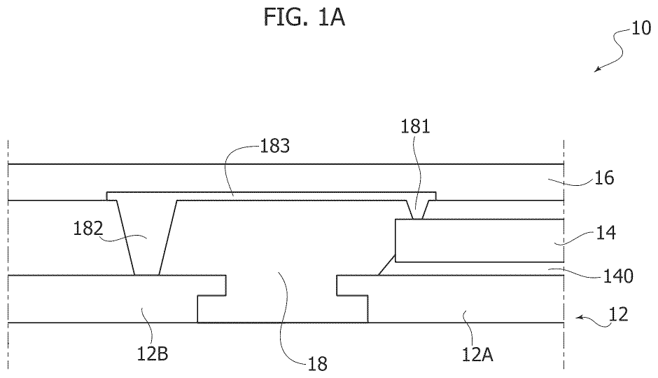

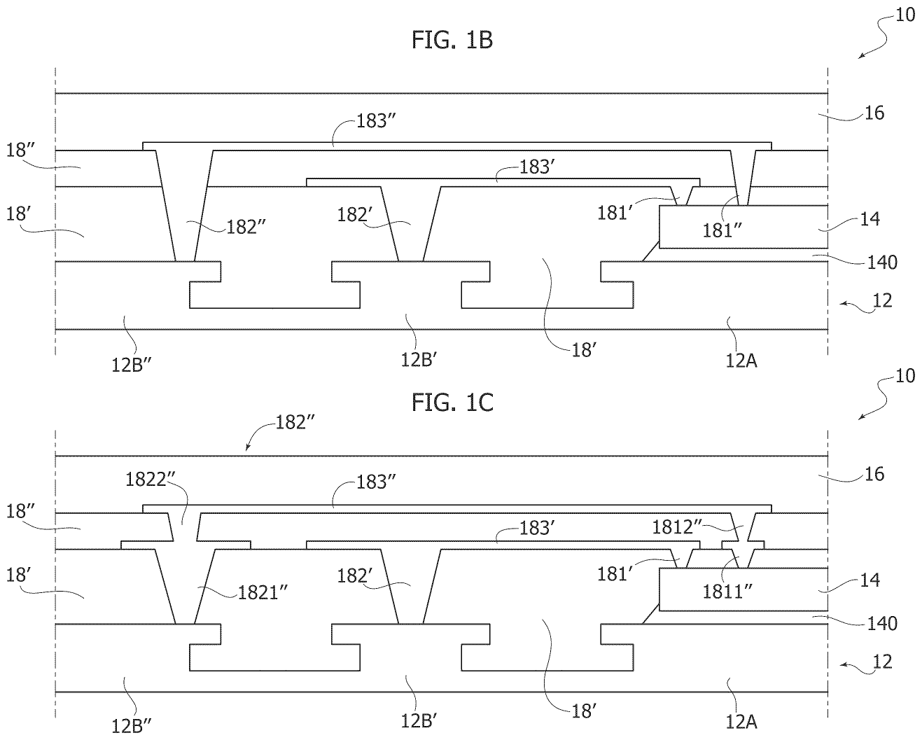

FIG. 1A is generally illustrative of the structure of an (integrated circuit—IC) semiconductor device 10.

For the sake of simplicity, in FIG. 1A (and in all the figures annexed herewith) only a portion of such a semiconductor device 10 is illustrated extending between two vertical dotted chain lines.

A semiconductor device 10 as illustrated in FIG. 1A (and in all the other figures annexed herewith) comprises a substrate (leadframe) 12 having one or more semiconductor chips or dice 14 arranged on respective die pads 12A via die attach material 140 (a die attach film (DAF), for instance) as well as electrically conductive formations coupling the semiconductor chip(s) 14 to leads 12B (outer pads) in the substrate (leadframe) 12.

Only one chip or die 14 mounted on a die pad 12A is illustrated here for simplicity.

The designation “leadframe” (or “lead frame”) is currently used (see, for instance the USPC Consolidated Glossary of the United States Patent and Trademark Office) to indicate a metal frame that provides support for an integrated circuit chip or die (here 14) as well as electrical leads to interconnect the integrated circuit in the die or chip to other electrical components or contacts.

Essentially, a leadframe such as the one indicated by the reference 12 comprises an array of electrically-conductive formations (or leads: see the lead 12B in FIG. 1A, for instance) that from an outline location extend inwardly in the direction of a semiconductor chip or die (14, for instance) thus forming an array of electrically-conductive formations from a die pad (here 12A) configured to have at least one semiconductor chip or die attached thereon.

As used herein, the terms chip/s and die/dice are regarded as synonymous.

An insulating encapsulation (epoxy resin, for instance) 16 is molded on the assembly thus formed to complete the plastic body of the device.

A device 10 as illustrated herein is intended to be mounted on a substrate such as a printed circuit board (PCB—not visible in the figures), using solder material, for instance.

Electrically conductive formations are provided to electrically couple die pads provided at the front or top surfaces of the chip 14 (not visible for reasons of scale) to selected ones of the leads (outer pads) 12B in the leadframe 12.

These electrically conductive formations may comprise a wire bonding pattern, or (if the current transferred to the output pads or leads 12B is significant, which is the case of power semiconductor devices) ribbons or clips.

FIG. 1A is exemplary of a solution (essentially as disclosed in various ones of the earlier patent documents assigned to companies of the STMicroelectronics group cited in the foregoing) where the electrically conductive formations coupling the chip or die 14 on the die pad 12A to the leads 12B are formed via LDS processing (laser structuring plus metal plating) a mass of LDS material 18 molded onto the chip or die 14 mounted on the leadframe 12.

Recourse to LDS technology facilitates replacing wires, clips or ribbons with lines/vias created by laser beam processing of an LDS material followed by metallization (growing metal such as copper via a plating process, for instance).

As discussed in the commonly assigned applications cited in the foregoing, for instance, electrically conductive die-to-lead coupling formations provided lad LDS processing of an LDS material 18 (once consolidated, e.g., via thermosetting) may comprise: first through mold vias (TMVs) 181 that extend through the LDS encapsulation 18 between the top (front) surface of the LDS encapsulation 18 and electrically-conductive pads (not visible for scale reasons) at the front or top surface of the chip or die 14; second through mold vias (TMVs) 182 that extend through the LDS encapsulation 18 between the top (front) surface of the LDS encapsulation 18 and corresponding leads 12B in the leadframe; and electrically-conductive lines or traces 183 that extend at the front or top surface of the LDS encapsulation 18 and electrically couple selected ones of the first vias 181 with selected ones of the second vias 182 to provide a desired die-to-lead electrical connection (routing) pattern between the chip or die 14 and the leads 12B.

Electrical components (e.g., passive components such as resistors, for instance) may possibly be arranged along one or more of the lines or traces 183.

Providing the electrically conductive die-to-lead formations 181, 182, and 183 essentially involves: structuring these formations in the LDS material 18, for instance, laser-drilling holes therein at the desired locations for the vias 181, 182; and growing electrically conductive material (a metal such as copper, for instance) at the locations previously activated (structured) via laser beam energy.

FIG. 1B is exemplary of the possibility of (notionally) extending the concept underlying the solution illustrated in FIG. 1A to a multi-level metallization where a first electrical coupling pattern and a second electrical coupling pattern are provided between the chip(s) or die/dice 14 and different sets of leads 12B′, 12B″ in the substrate (leadframe) 12.

As illustrated in FIG. 1B, a first electrical coupling pattern comprises: first through mold vias (TMVs) 181′ that extend through a first LDS encapsulation layer 18′ between the top (front) surface of the LDS encapsulation layer 18′ and electrically-conductive pads (not visible for scale reasons) at the front or top surface of the chip or die 14; second through mold vias (TMVs) 182′ that extend through the first LDS encapsulation layer 18′ between the top (front) surface of the first LDS encapsulation layer 18′ and corresponding leads 12B′ in the leadframe; and electrically-conductive lines or traces 183′ that extend at the front or top surface of the LDS encapsulation layer 18′ and electrically couple selected ones of the first vias 181′ with selected ones of the second vias 182′ to provide a (first) desired die-to-lead electrical connection (routing) pattern between the chip or die 14 and the leads 12B′.

As illustrated in FIG. 1B, a second electrical coupling pattern comprises: through mold vias (TMVs) 181″ that extend through the (first) LDS encapsulation 18′ as well as through a second LDS encapsulation 18″ (formed onto the first LDS encapsulation 18′) between the top (front) surface of the LDS encapsulation 18″ and electrically-conductive pads (not visible for scale reasons) at the front or top surface of the chip or die 14; further through mold vias (TMVs) 182″ that extend through the first LDS encapsulation 18′ as well as through the second LDS encapsulation 18″ between the top (front) surface of the second LDS encapsulation layer 18″ and corresponding leads 12B″ in the leadframe; and electrically-conductive lines or traces 183″ that extend at the front or top surface of the second LDS encapsulation layer 18″ and electrically couple selected ones of the first vias 181″ with selected ones of the second vias 182″ to provide a (second) desired die-to-lead electrical connection (routing) pattern between the chip or die 14 and the leads 12B″.

It is noted that the same concept exemplified in FIG. 1B can be extended to more than two stacked coupling patterns “structured” or “written” into more than two layers of LDS material.

As discussed in the introductory portion of this description, while notionally feasible (and capable of providing mutual electrical insulation of the first and second electrically coupling patterns as desired, irrespective of the related layouts) the arrangement exemplified in FIG. 1B is penalized by aspect ratio constraints related to the plating process, so that deep vias extending through plural LDS molding compound levels or layers (see the vias 181″ and 182″ in FIG. 1B, for instance) tend to be fairly large at their top portion, which puts constraints on interconnection density and package miniaturization.

According to solutions as described herein, these issues are addressed as illustrated in FIG. 1C. Here again, a multi-level arrangement is considered in order to provide a (first) electrical coupling pattern and a (further) electrical coupling pattern are provided between the chip(s) or die/dice 14 and different sets of leads 12B′, 12B″ in the substrate (leadframe) 12.

In solutions as illustrated in FIG. 1C, the first electrical coupling pattern for the chip or die 14 is essentially as illustrated in FIG. 1B and thus comprises: through mold vias (TMVs) 181′ that extend through a first LDS encapsulation layer 18′ between the top (front) surface of the LDS encapsulation layer 18′ and electrically-conductive pads (not visible for scale reasons) at the front or top surface of the chip or die 14; through mold vias (TMVs) 182′ that extend through the LDS encapsulation layer 18′ between the top (front) surface of the LDS encapsulation layer 18′ and corresponding leads 12B′ in the leadframe; and electrically-conductive lines or traces 183′ that extend at the front or top surface of the LDS encapsulation layer 18′ and electrically couple selected ones of the vias 181′ with selected ones of the vias 182′ to provide a (first) desired die-to-lead electrical connection (routing) pattern between the chip or die 14 and the leads 12B′.

In solutions as illustrated in FIG. 1C, a further electrical coupling pattern for the chip or die 14 comprises: multi-stage through mold vias (TMVs) 1811″, 1812″ that include a stage 1811″ extending through the first LDS encapsulation layer 18′ as well as a further stage 1812″ stacked (aligned) on the stage 1811″ and extending through the further LDS encapsulation layer 18″, so that the multi-stage through mold vias 1811″, 1812″ extend between the top (front) surface of the further LDS encapsulation 18″ and electrically-conductive pads (not visible for scale reasons) at the front or top surface of the chip or die 14; multi-stage through mold vias (TMVs) 1821″, 1822″ that include a stage 1821″ extending through the LDS encapsulation layer 18′ as well as a further stage 1822″ stacked (aligned) on the stage 1821″ and extending through the further LDS encapsulation layer 18″, so that the multi-stage through mold vias 1821″, 1822″ extend between the top (front) surface of the further LDS encapsulation layer 18″ and corresponding leads 12B″ in the leadframe 12; and electrically-conductive lines or traces 183″ that extend at the front or top surface of the further LDS encapsulation layer 18″ and electrically couple the stages 1812″ of selected ones of the vias 181″ with the stages 1822″ of selected ones of the vias 182″ to provide a (further) desired die-to-lead electrical connection (routing) pattern between the chip or die 14 and the leads 12B″.

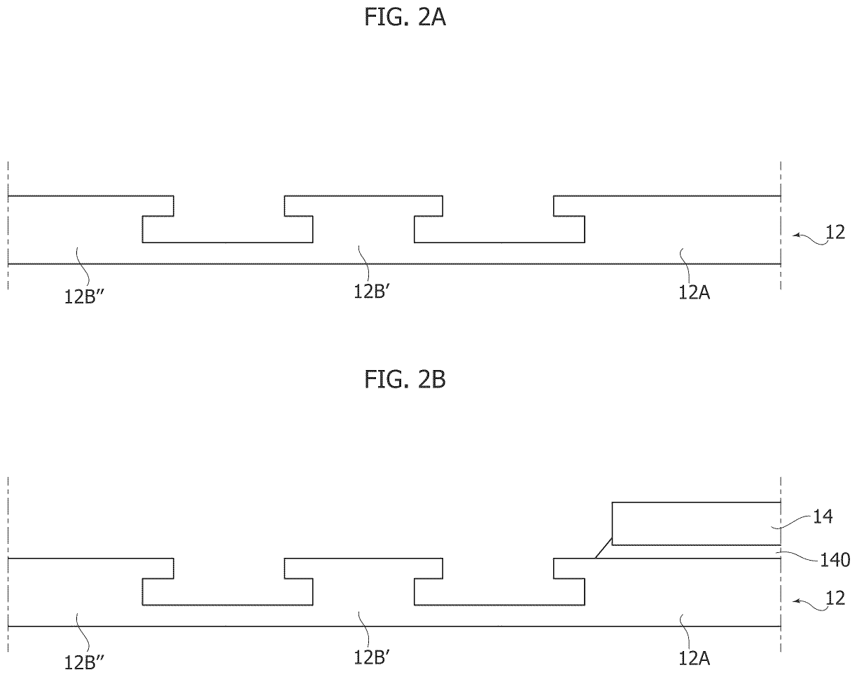

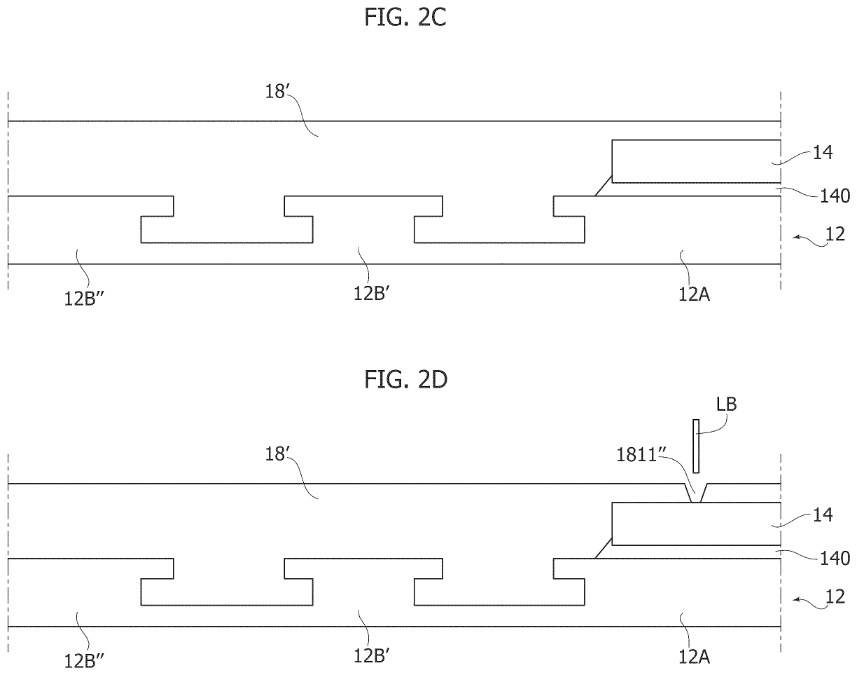

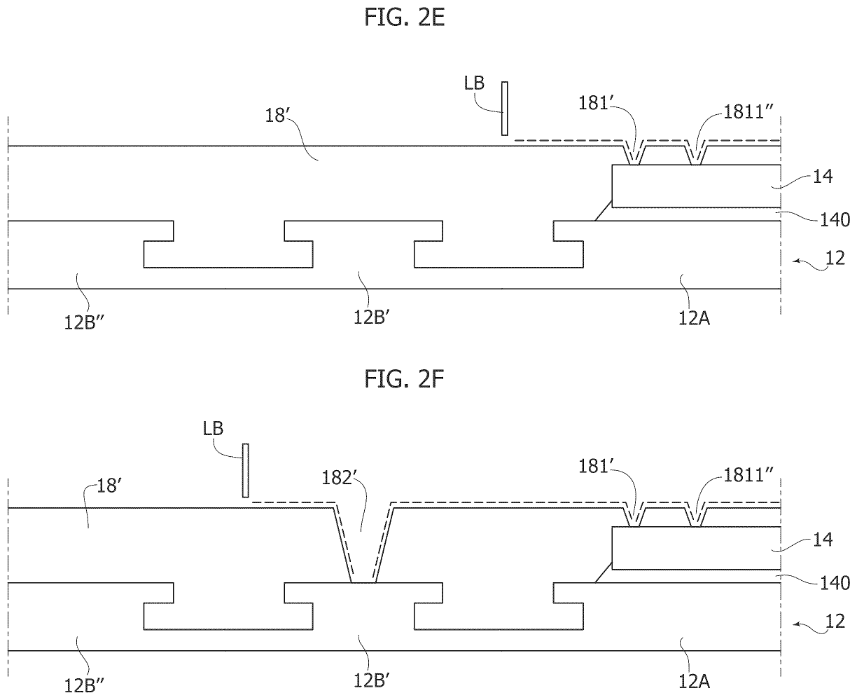

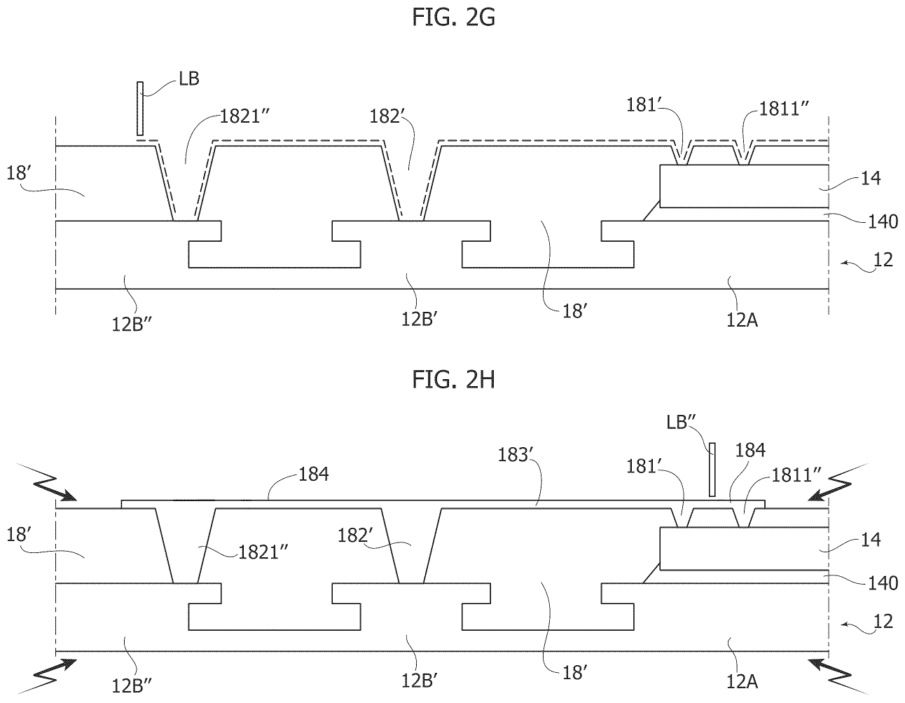

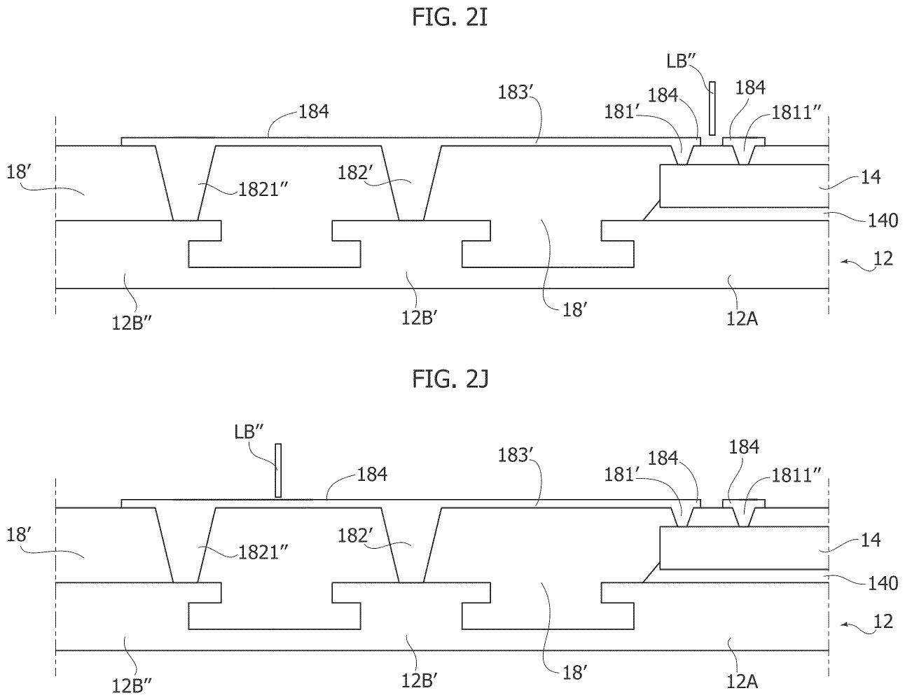

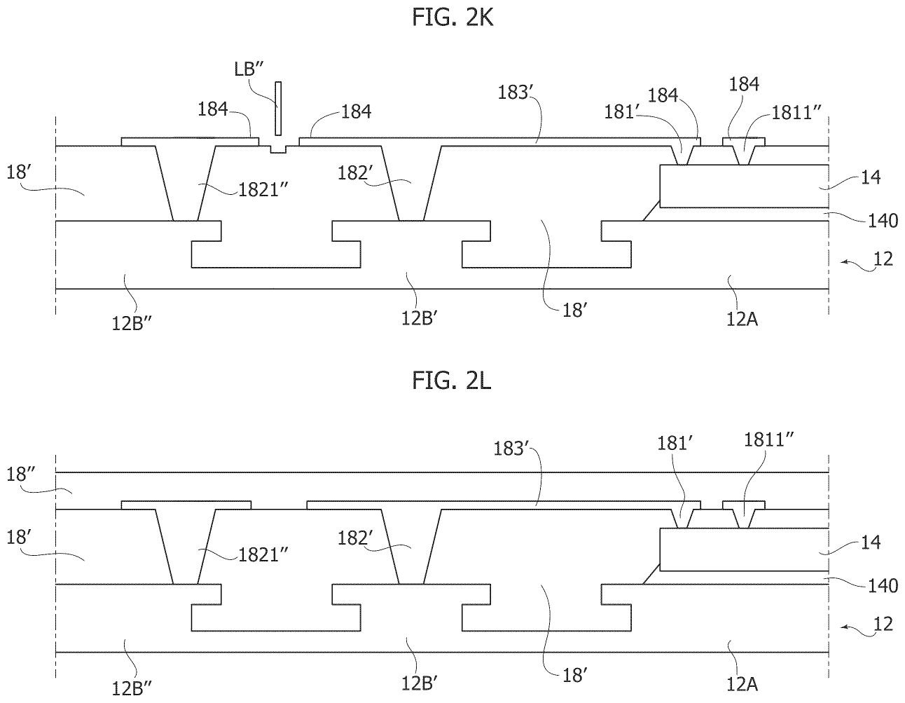

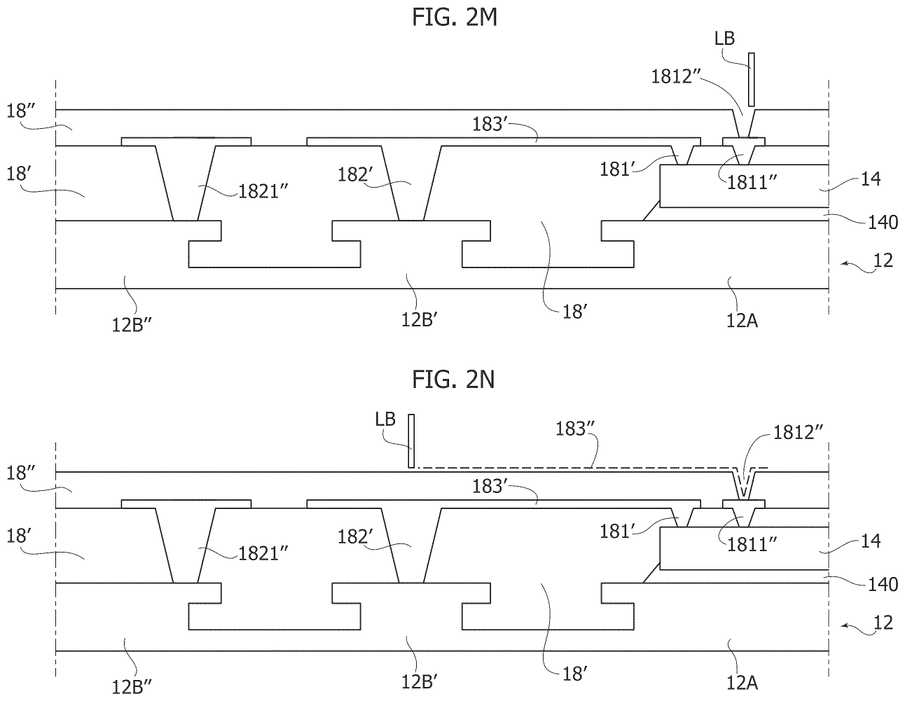

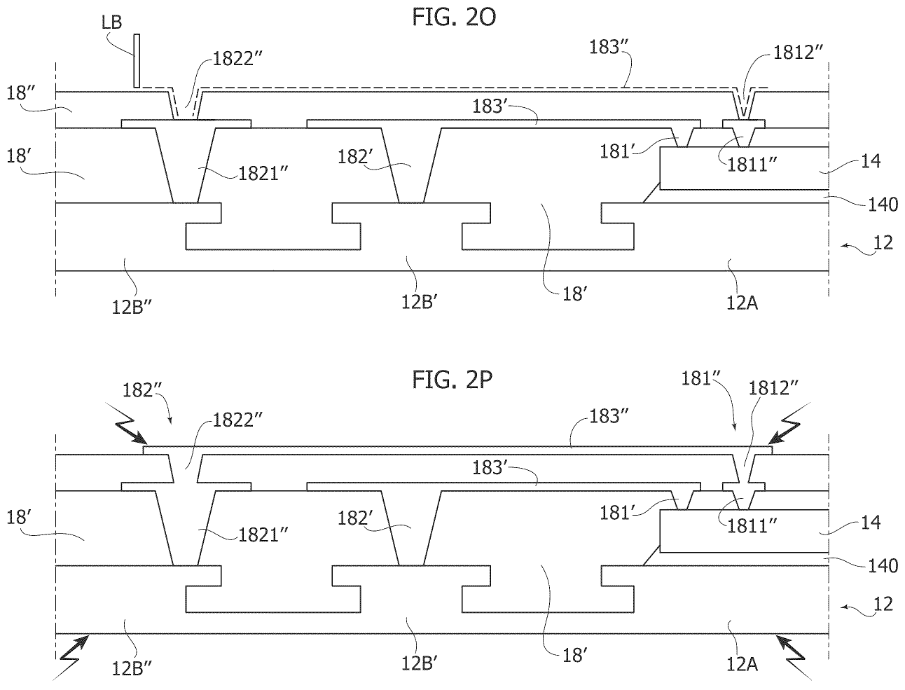

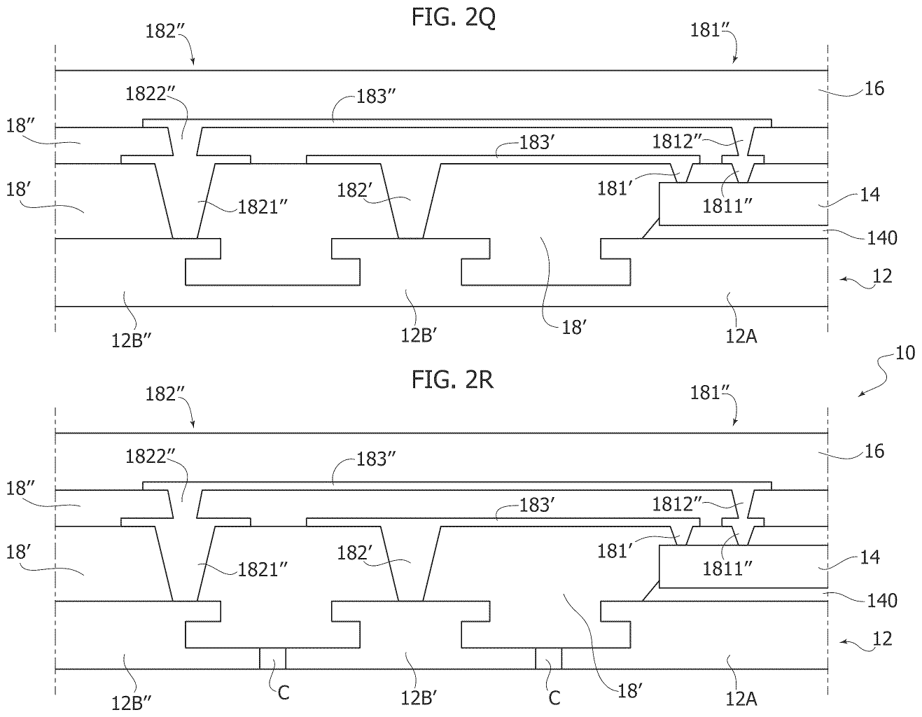

FIGS. 2A through 2R illustrate possible steps in a process of manufacturing an IC semiconductor device according to solutions as described herein. Such process takes advantage of possible synergy in producing the through mold vias 181′, 182′ and the (first) stages 1811″ and 1821″ of the through mold vias 181″, 182″ through the (first) layer 18′ of LDS material.

It will be otherwise appreciated that the process represented in FIGS. 2A to 2R is merely exemplary insofar as: one or more of the steps illustrated can be omitted, performed in a different manner (with other tools or processes, for instance) and/or replaced by other steps; additional steps may be added; one or more steps can be carried out in a sequence different from the sequence illustrated; one or more steps illustrated in connection with any of the sequences illustrated can be exchanged with other steps.

FIG. 2A illustrate the structure of a (portion of) substrate such as a metal (copper, for instance) leadframe 12 including a die pad 12A and leads 12B′, 12B″. For simplicity it may be assumed that the leads are arranged in a first array (leads 12B′) and a second array (leads 12B″, arranged around the array of leads 12B′, for instance).

FIG. 2B illustrates a chip or die 14 that is attached onto the die pad 12A via die attach material 140 (a die attach film (DAF), for instance) as conventional in the art.

It is once more noted that showing only one die pad 12A having only one chip or die 14 mounted thereon is merely for simplicity and ease of explanation.

As noted, the substrate 12 may be a leadframe, possibly of the pre-molded type. FIG. 2C a (first) mass of LDS material 18′ molded onto the chip or die 14 attached onto the die pad 12A.

Laser direct structuring (LDS) is a laser-based machining technique now widely used in various sectors of the industrial and consumer electronics markets, for instance for high-performance antenna integration, where an antenna design can be directly formed onto a molded plastic part. In an exemplary process, molded parts can be produced with commercially available insulating resins that include additives suitable for the LDS process; a broad range of resins such as polymer resins like PC, PC/ABS, ABS, LCP are currently available for that purpose. A laser beam can be used to transfer (“structure”, “activate”, “write”) a desired electrically conductive pattern onto a plastic molding that may then be subjected to metallization to finalize a desired conductive pattern.

Metallization may involve electroless plating followed by electrolytic plating.

Electroless plating, also known as chemical plating, is a class of industrial chemical processes that creates metal coatings on various materials by autocatalytic chemical reduction of metal cations in a liquid bath.

In electrolytic plating, an electric field between an anode and a workpiece, acting as a cathode, forces positively charged metal ions to move to the cathode where they give up their charge and deposit themselves as metal on the surface of the workpiece.

LDS is oftentimes referred to also as laser direct writing (LDW), direct copper interconnection (DCI), laser induced strip interconnection (LISI). LISIPACK™ is a trade designation used by companies of the STMicroelectronics group to designate related products and processes.

FIGS. 2A, 2B, and 2C thus illustrate the steps of arranging one or more integrated circuit, IC semiconductor chips 14 (only one is shown for simplicity) on a die pad 12A in a substrate 12 as a metal leadframe. The substrate 12 includes a first set 12B′ of electrically conductive leads as well as one or more further sets of electrically conductive leads (only one further set 12B″ is shown here for simplicity).

The integrated circuit semiconductor chip 14 is coupled to electrically conductive leads in the first set 12B′ by: molding a (first) layer 18′ of laser direct structuring, LDS encapsulation material onto the semiconductor chip 14 arranged onto the die pad 12A in the substrate 12; and applying (first) LDS processing—in a manner known per se to those of skill in the art—to the layer 18′ of LDS encapsulation material to provide in the layer 18′ of LDS encapsulation material through mold vias 181′, 182′ that extend through the first layer 18′ of LDS encapsulation material i) towards the semiconductor chip 14 and ii) towards electrically conductive leads in the first set 12B′ of electrically conductive leads, respectively.

The integrated circuit semiconductor chip 14 is likewise intended to be coupled to electrically conductive leads in the further set 12B″ by: applying the (first) LDS processing to the (first) layer 18′ of LDS encapsulation material to provide in the layer 18′ of LDS encapsulation material a pattern of (first) stages of through mold vias 1811″, 1821″ that extend through the layer 18′ of LDS encapsulation material i) towards the semiconductor chip 14 and ii) towards electrically conductive leads in the further set 12B″ of electrically conductive leads, respectively.

In solutions as disclosed herein: one (or more) further layers (only one such layer 18″ is illustrated for simplicity) of laser direct structuring, LDS encapsulation material is/are molded onto the first layer 18′ of LDS encapsulation material having the through mold vias 181′, 182′ and the stages of through mold vias 1811″, 1821″ extending therethrough; and (further) LDS processing is applied to the layer 18″ of LDS encapsulation material to provide in the further layer 18″ of LDS encapsulation material further stages of through mold vias 1812″, 1822″ that extend through the further layer 18″ of LDS encapsulation material towards first stages of through mold vias 1811″, 1821″ in the first pattern of first stages of through mold vias 1811″, 1821″.

Specifically, FIGS. 2D, 2E, 2F, and 2G are illustrative of laser beam energy LB applied locally to the (first) mass of LDS material 18′ molded onto the chip or die 14 attached onto the die pad 12A to “structure” or “write” therein (essentially via laser drilling) vias and traces that are then metallized (plated, with copper for instance), as illustrated in FIG. 2H, to produce electrically conductive formations through and over the (first) layer of LDS material 18′.

Such laser structuring (writing) and subsequent metallization or plating (via electroless plus electrolytic plating) is conventional in the art and a detailed description of the (otherwise conventional) steps involved therein will not be reproduced for brevity.

Symbols in the form of small “zig-zag arrows” at the corners of FIG. 2H highlight that solutions as described herein facilitate electrolytic plating in so far as (electrically activated) surfaces suited to act as electrodes in an electrolytic bath remain exposed and thus available for contact.

For the purposes herein (and referring to the sequence of FIGS. 2D to 2H) one may note that laser beam LDS processing of the layer of LDS material 18′ may involve “scanning” such material with a laser beam source LB (from right to left in the sequence of FIGS. 2D to 2G) to form therein: the first stage 1811″ of the vias 181″; the vias 181′; the vias 182′; and the first stage 1821″ of the vias 182″.

Such first LDS processing of the first layer 18′ of LDS encapsulation material also provides, in the first layer 18′ of LDS encapsulation material, electrically conductive lines or traces 183′ that extend over the layer 18′ of LDS encapsulation material and couple therebetween selected ones of the through mold vias 181′ and 182′ thus completing a first pattern of electrical formation coupling the chip or die 14 with electrically conductive leads in the first set of leads 12B′.

According to the circuit topology LDS processing of the layer 18′ of LDS encapsulation material may also produce additional traces, designated 184, at the front or top surface of the layer of LDS material 18′ with these traces 184 coupling (in fact mutually short-circuiting) at least part of: the stage 1811″ of the vias 181″ and the vias 181′; the vias 182′ and the first stage 1821″ of the vias 182″.

These latter additional “shorting” traces 184 may end up by couple inner and outer vias (and thus inner and “outer” leads 12B′ and 12B″) which may undesirable.

FIGS. 2I, 2J and 2K thus illustrate the action and the result of these (sacrificial) shorting lines or traces 184 being severed (cut) to preserve mutual insulation of inner and outer vias and leads 12B′ and 12B″ as desired

Such cutting/severing may be via laser beam energy LB″ (laser ablation). While a different reference symbol for LB′ as used in FIGS. 2D to 2G is used in FIGS. 2I, 2J and 2K a same laser beam source can be used for cutting the traces 184.

Ablation as indicated by LB″ thus depend on the circuit layout: in case a connection of inner and outer vias is desirable, the trace in between is not ablated.

FIG. 2L illustrates a (second) mass of LDS material 18″ molded onto the structure of FIG. 2K.

Here again, an insulating resin that includes additives suitable for the LDS process can be used. This may be the same LDS material of the first mass or layer of LDS material 18′ or a different LDS material provided this material exhibits adequate adhesion and absence of delamination as desired.

Again, a laser beam LB can be used to transfer (“structure” or “write”) a desired electrically conductive pattern into the LDS material 18″ that may then be subjected to metallization to finalize a desired conductive pattern.

FIGS. 2M, 2N, and 2O are illustrative of laser beam energy LB being applied locally to the (second) mass of LDS material 18″ to “structure” or “write” therein (essentially via laser drilling) vias and traces that are then metallized (plated, with copper for instance), as illustrated in FIG. 2P, to produce electrically conductive formations through and over the (second) layer of LDS material 18″.

As already noted in connection with the (first) layer of LDS material 18′, such laser structuring (writing) and subsequent metallization or plating (via electroless plus electrolytic plating) is conventional in the art and a detailed description of the (otherwise conventional) steps involved therein will not be reproduced for brevity.

Again, symbols in the form of small “zig-zag arrows” at the corners of FIG. 2P highlight that solutions as described herein facilitate electrolytic plating also in the case of the (second) layer of LDS material 18″ in so far as surfaces suited to act as electrodes in an electrolytic bath again remain exposed and thus available for contact.

Referring to the sequence of FIGS. 2M to 2O one may note that laser beam LDS processing of the layer of LDS material 18″ may involve “scanning” such material with a laser beam source LB (from right to left in the sequence of FIGS. 2M to 2O) to form therein: the second stage 1812″ of the vias 181″; the second stage 1822″ of the vias 182″.

The LDS processing LB of the further layer 18″ of LDS encapsulation material also provides in the further layer 18″ of LDS encapsulation material also the further electrically conductive lines 183″ that extend over the further layer 18″ of LDS encapsulation material and couple selected ones of the further stages of through mold vias 1812″, 1822″ thus completing a further pattern of electrical formations that couple the chip or die 14 with electrically conductive leads in the further set of leads 12B″.

It is noted that LDS processing LB of the further layer 18″ of LDS encapsulation material is advantageously performed in such a way that the further stages of through mold vias 1812″, 1822″ extend through the further layer 18″ of LDS encapsulation material in alignment with respective first stages of through mold vias 1811″, 1821″.

The further stages of through mold vias 1812″, 1822″ being aligned with respective first stages of through mold vias 1811″, 1821″ gives rise to columnar through mold vias 181″, 182″ that extend through the first layer 18′ and the further layer 18″ of LDS encapsulation material.

FIG. 2Q illustrates insulating encapsulation material 16 (of any known type to those of skill in the art, epoxy resin, for instance, thus non-LDS material) molded onto the structure of FIG. 2P to complete the plastic body (package) of the device 10, with the encapsulation 16 covering the second stages 1812″, 1822″ of the vias 181″ and 182″ plus the traces 183″.

FIG. 2R illustrates possible completion of the device 10 with the leads 12B′ separated and thus insulated from the leads 12B″ with the metal structure of the substrate (leadframe) 12 cut (via etching, as otherwise conventional in the art) at intermediate locations C therebetween at the back or bottom surface of the substrate 12, opposite to the chip(s) or die/dice 14.

It is noted that the underlying principle of providing “multi-stage” through-mold vias such as the vias 181″ and 182″ including two stages 1811″, 1812″ and 1821″, 1822″ extending through two superposed layers 18′ and 18″ of LDS material can be extended to more than two stages.

In that way, the advantage can be retained that, with each stage having an aspect ratio (relationship between width and height) of approximately 1:1 (this is just by way of example), a multi-stage columnar through-mold via can result from superposing a number n of such stages with such a columnar through-mold via having a height-to-width ratio nearly equal to n:1, and thus a much leaner outline which facilitates achieving increased line density and reduced device size.

It is noted that, especially in case of such multi-stage through mold vias including more than two stages, the step of providing electrically conductive such as the lines 183″ can be performed only for the uppermost stages in the multi-stage through mold vias.

Whatever the details of implementation both the (first) LDS processing of the first layer 18′ of LDS encapsulation material and the (further) LDS processing of the further layer 18″ of LDS encapsulation material may comprise laser beam structuring of selected locations (see, for instance, the locations indicated by references 181′, 182′, 183′; 1811″, 1821″, 1812″, 1822″, 183″) of the LDS encapsulation material (both layers 18′ and 18″), and growing electrically conductive material (copper, for instance) selected locations 181′, 182′, 183′; 1811″, 1821″, 1812″, 1822″, 183″ of the LDS encapsulation material at which laser beam structuring has been applied.

Growing electrically conductive material advantageously includes (possibly following electroless plating) growing electrically conductive material via an electrolytic current flow path that, as represented by the “zig-zag arrow” symbols reproduced in FIG. 2H and FIG. 2P, extend between the substrate (leadframe) 12 and the laser beam structured selected locations 181′, 182′, 183′; 1811″, 1821″, 1812″, 1822″, 183″ of the LDS encapsulation material that, in both layers 18′ are 18″ remain exposed at the time of such electrolytic growth of conductive material such as copper.

Without prejudice to the underlying principles, the details and embodiments may vary, even significantly, with respect to what has been described in the foregoing, by way of example only, without departing from the extent of protection.

The claims are an integral part of the technical teaching on the embodiments as provided herein.

The extent of protection is determined by the annexed claims.

1. A method, comprising:
arranging a semiconductor chip on a die pad in a substrate including a first set of electrically conductive leads and at least one further set of electrically conductive leads;
coupling the semiconductor chip to electrically conductive leads in the first set of electrically conductive leads by molding a layer of laser direct structuring (LDS) encapsulation material onto the semiconductor chip arranged onto the die pad in the substrate and applying LDS processing to the layer of LDS encapsulation material to provide through mold vias extending through the layer of LDS encapsulation material towards the semiconductor chip as well as through mold vias extending through the layer of LDS encapsulation material towards electrically conductive leads in the first set of electrically conductive leads; and
coupling the semiconductor chip to electrically conductive leads in the further set of electrically conductive leads by:
applying LDS processing to the layer of LDS encapsulation material to provide stages of through mold vias extending through the layer of LDS encapsulation material towards the semiconductor chip as well as stages of through mold vias extending through the layer of LDS encapsulation material towards electrically conductive leads in the further set of electrically conductive leads;
molding a further layer of LDS encapsulation material onto the layer of LDS encapsulation material having the through mold vias and the stages of through mold vias extending therethrough; and
applying LDS processing to the further layer of LDS encapsulation material to provide further stages of through mold vias extending through the further layer of LDS encapsulation material towards stages of through mold vias in the layer of LDS encapsulation material.

2. The method of claim 1, comprising applying LDS processing to the further layer of LDS encapsulation material to provide in the further layer of LDS encapsulation material further stages of through mold vias extending through the further layer of LDS encapsulation material in alignment with respective stages of through mold vias in the layer of LDS encapsulation material, wherein said further stages of through mold vias in the further layer of LDS encapsulation material and said respective stages of through mold vias in the layer of LDS encapsulation material provide columnar through mold vias extending through the layer of LDS encapsulation material and the further layer of LDS encapsulation material.

3. The method of claim 1, comprising applying LDS processing to the layer of LDS encapsulation material to provide in the layer of LDS encapsulation material electrically conductive lines extending over the layer of LDS encapsulation material and coupling selected ones of the through mold vias in the layer of LDS encapsulation material.

4. The method of claim 1, comprising applying LDS processing to the further layer of LDS encapsulation material to provide in the further layer of LDS encapsulation material further electrically conductive lines extending over the further layer of LDS encapsulation material and coupling selected ones of the further stages of through mold vias in the further layer of LDS encapsulation material.

5. The method of claim 1, wherein applying LDS processing to the layer of LDS encapsulation material produces electrically conductive shorting lines extending over the layer of LDS encapsulation material and coupling through mold vias extending through the layer of LDS encapsulation material with stages of through mold vias extending through the layer of LDS encapsulation material, wherein the method further comprises severing said electrically conductive shorting lines before applying LDS processing to the further layer of LDS encapsulation material.

6. The method of claim 5, where severing comprises applying a laser ablation to the electrically conductive shorting lines.

7. The method of claim 1, comprising electrically decoupling the set of electrically conductive leads and the at least one further set of electrically conductive leads, wherein electrically decoupling preferably comprises etching the substrate having the semiconductor chip arranged on said die pad.

8. The method of claim 1, wherein LDS processing of the layer of LDS encapsulation material and of the further layer of LDS encapsulation material comprise:
laser beam structuring selected locations of the LDS encapsulation material and the further LDS encapsulation material; and
growing electrically conductive material at said laser beam structured selected locations.

9. The method of claim 8. comprising electrolytically growing electrically conductive material via an electrolytic current flow path between said laser beam structured selected locations and said substrate.

10. A method, comprising:
mounting a semiconductor chip to a leadframe;
encapsulating the semiconductor chip in a first layer of laser direct structuring (LDS) encapsulation material;
applying LDS processing to the first layer of LDS encapsulation material to form a first via extending through the first layer of LDS encapsulation material to the leadframe, a second via extending through the first layer of LDS encapsulation material to the semiconductor chip, and a first electrically conductive line connecting the first via to the second via;
severing the first electrically conductive line between the first and second vias;
applying a second layer of LDS encapsulation material over the first and second vias, the severed first electrically conductive line, and the first layer of LDS encapsulation material; and
applying LDS processing to the second layer of LDS encapsulation material to form a third via extending through the second layer of LDS encapsulation material to the first via, a fourth via extending through the second layer of LDS encapsulation material, and a second electrically conductive line connecting the third via to the fourth via.

11. The method of claim 10, wherein the first and third vias form columnar through mold vias.

12. The method of claim 10, where severing comprises applying a laser ablation to the first electrically conductive line.

13. The method of claim 10, wherein applying LDS processing comprises:
laser beam structuring selected locations of LDS encapsulation material; and
growing electrically conductive material at said selected locations.

14. The method of claim 13, comprising electrolytically growing electrically conductive material via an electrolytic current flow path at said selected locations.

15. A device, comprising:
a semiconductor chip arranged on a die pad in a substrate including a first set of electrically conductive leads and at least one further set of electrically conductive leads;
electrically conductive formations coupling the semiconductor chip to electrically conductive leads in the first set of electrically conductive leads, wherein the electrically conductive formations comprising through mold vias laser direct structured through a layer of laser direct structuring (LDS) encapsulation material molded onto the semiconductor chip, wherein the through mold vias include through mold vias extending towards the semiconductor chip and through mold vias extending towards electrically conductive leads in the first set of electrically conductive leads; and
further electrically conductive formations coupling the semiconductor chip to electrically conductive leads in the further set of electrically conductive leads, wherein the further electrically conductive formations comprise:
stages of through mold vias laser direct structured through the layer of LDS encapsulation material, wherein the stages of through mold vias comprise stages of through mold vias extending towards the semiconductor chip as well as stages of through mold vias extending towards electrically conductive leads in the further set of electrically conductive leads; and
further stages of through mold vias laser direct structured through a further layer of LDS encapsulation material molded onto the layer of LDS encapsulation material, wherein the further stages of through mold vias extend through the further layer of LDS encapsulation material towards stages of through mold vias laser direct structured in the layer of LDS encapsulation material.

16. The device of claim 15, comprising electrically conductive lines extending over the layer of LDS encapsulation material and coupling selected ones of the through mold vias in the layer of LDS encapsulation material.

17. The device of claim 16, wherein certain ones of the electrically conductive lines include a severed end to isolate the through mold vias in the layer of LDS encapsulation material which are connected to the certain ones of the electrically conductive lines with severed ends.

18. The device of claim 15, comprising further electrically conductive lines extending over the further layer of LDS encapsulation material and coupling selected ones of the further stages of through mold vias in the further layer of LDS encapsulation material.

19. A device, comprising:
a leadframe including a die pad and an electrically conductive lead;
a semiconductor chip arranged on the die pad;
a first layer of laser direct structuring (LDS) encapsulation material encapsulating the semiconductor chip;
a first via extending through the first layer of LDS encapsulation material to the electrically conductive lead;
a second via extending through the first layer of LDS encapsulation material to the semiconductor chip;
a first electrically conductive line including a first portion extending from the first via and a second portion extending from the second via, where the first electrically conductive line is severed between the first and second portions;
a second layer of LDS encapsulation material over the first and second vias, the severed first electrically conductive line, and the first layer of LDS encapsulation material; and
a third via extending through the second layer of LDS encapsulation material to the first via, a fourth via extending through the second layer of LDS encapsulation material, and a second electrically conductive line connecting the third via to the fourth via.

20. The device of claim 19, wherein the first and third vias form columnar through mold vias.
